(19) United States
(12) Patent Application Publication
(10) Pub. No.: US 2026/0202978 A1
(43) Pub. Date: Jul. 16, 2026

(54) MEMORY SYSTEM, ELECTRONIC DEVICE COMPRISING SAME, AND REFRESH CONTROL METHOD

(71) Applicant: Samsung Electronics Co., Ltd., Suwon-si (KR)

(72) Inventors: Jaekab LEE, Suwon-si (KR); Junseok PARK, Suwon-si (KR); Changmi SHIN, Suwon-si (KR)

(21) Appl. No.: 19/555,367

(22) Filed: Mar. 3, 2026

Related U.S. Application Data
(63) Continuation of application No. PCT/KR2024/012143, filed on Aug. 14, 2024.

(30) Foreign Application Priority Data
Sep. 4, 2023 (KR) 10-2023-0116786
Oct. 23, 2023 (KR) 10-2023-0142095

(51) Int. Cl. G06F 3/06

(52) U.S. Cl. CPC G06F 3/0632; G06F 3/0604; G06F 3/0659; G06F 3/0673

(57) ABSTRACT

An electronic device is provided. The electronic device includes a display, memory, including one or more storage media, storing instructions including a refresh period, and at least one processor communicatively coupled to the display and the memory, wherein the instructions, when executed by the at least one processor individually or collectively, cause the electronic device to determine a first transmission delay time based on a refresh interval (tREFI) corresponding to a first refresh period outputted from the memory, apply the first transmission delay time to the refresh interval, when a second refresh period is outputted from the memory, transmit a first refresh command to the memory after delaying by an offset of the first transmission delay time based on a refresh interval corresponding to the second refresh period, and when a predetermined time expires after the first transmission delay time is determined, display, via the display, a user interface that induces updating the first transmission delay time to a second transmission delay time.

### CROSS-REFERENCE TO RELATED APPLICATION(S)

This application is a continuation application, claiming priority under 35 U.S.C. § 365(c), of an International application No. PCT/KR2024/012143, filed on Aug. 14, 2024, which is based on and claims the benefit of a Korean patent application number 10-2023-0116786, filed on Sep. 4, 2023, in the Ministry of Intellectual Property (MOIP), and of a Korean patent application number 10-2023-0142095, filed on Oct. 23, 2023, in the Ministry of Intellectual Property (MOIP), the disclosure of each of which is incorporated by reference herein in its entirety.

### BACKGROUND

### 1. Field

The disclosure relates to a memory system, an electronic device including the same, and a refresh control method.

### 2. Description of Related Art

With the development of digital technology, various electronic devices, which are capable of communicating and processing personal information while moving, such as a mobile communication terminal, an electronic notebook, a smartphone, a tablet personal computer (PC), and a wearable device are being released.

Various types of memory devices is provided in the electronic device. For example, dynamic random access memory (DRAM) which is capable of being used as working memory is provided in the electronic device.

The above information is presented as background information only to assist with an understanding of the disclosure. No determination has been made, and no assertion is made, as to whether any of the above might be applicable as prior art with regard to the disclosure.

### SUMMARY

The DRAM described above includes a memory cell including a capacitor and a transistor and stores data by using charges stored in the capacitor.

In general, the charges stored in the capacitor leaks through various paths over time. This means that the data stored in the memory cell are lost. In this regard, the DRAM prevents the loss of data by performing a refresh operation through a precharge operation, which is an operation of selecting and activating a row of memory cells and closing the word line again.

However, the refresh operation causes power consumption, and the power consumption increases as the number of refresh operations increases. The power consumption due to the refresh operation reduces the efficiency of power of the DRAM.

Aspects of the disclosure are to address at least the above-mentioned problems and/or disadvantages and to provide at least the advantages described below. Accordingly, an aspect of the disclosure is to provide a memory system for reducing power consumption caused by the refresh operation, an electronic device including the same, and a refresh control method.

Another aspect of the disclosure is to provide a memory system for reducing the number of times of transmission of a refresh command by applying an offset to a transmission interval of the refresh command, an electronic device, and a refresh control method.

Additional aspects will be set forth in part in the description which follows and, in part, will be apparent from the description, or may be learned by practice of the presented embodiments.

In accordance with an aspect of the disclosure, an electronic device is provided. The electronic device includes a display, memory, including one or more storage media, storing instructions including a refresh period, and at least one processor communicatively coupled to the display and the memory, wherein the instructions, when executed by the at least one processor individually or collectively, cause the electronic device to determine a first transmission delay time based on a refresh interval (tREFI) corresponding to a first refresh period outputted from the memory, apply the first transmission delay time to the refresh interval, when a second refresh period is outputted from the memory, transmit a first refresh command to the memory after delaying by an offset of the first transmission delay time based on a refresh interval corresponding to the second refresh period, and when a predetermined time expires after the first transmission delay time is determined, display, via the display, a user interface that induces updating of the first transmission delay time to a second transmission delay time.

In accordance with another aspect of the disclosure, a memory system is provided. The memory system includes volatile memory including a memory controller including a memory controller, including one or more storage media, storing instructions including a refresh period, and at least one processor communicatively coupled to the volatile memory, wherein the instructions, when executed by the at least one processor individually or collectively, cause the memory system to determine a transmission delay time (a) based on a refresh interval (tREFI) corresponding to a first refresh period outputted from the memory controller, and when a second refresh period is outputted from the memory controller, transmit a refresh command to the volatile memory after delaying by an offset of the transmission delay time (a) based on a refresh interval corresponding to the second refresh period, and wherein the instructions, when executed by the at least one processor individually or collectively, further cause the memory system, in determining the transmission delay time, to write a test pattern to the volatile memory, perform a read operation on the volatile memory at each test period that increases by specific time intervals based on the refresh interval corresponding to the first refresh period, and determine the transmission delay time based on a time at which a pattern identical to the test pattern is read.

In accordance with another aspect of the disclosure, one or more non-transitory computer-readable storage media storing one or more computer programs including computer-executable instructions that, when executed by one or more processors of an electronic device individually or collectively, cause the electronic device to perform operations are provided. The operations include writing, by the electronic device, a test pattern to memory of the electronic device, performing, by the electronic device, based on a refresh interval (tREFI) corresponding to a first refresh period outputted from the memory, a read operation on the memory at each test period that increases by a specific time interval, determining, by the electronic device, a transmission delay time based on a time at which a pattern identical to the test pattern is read, applying, by the electronic device, the transmission delay time to a refresh interval corresponding to a refresh period outputted from the memory, and when a second refresh period is outputted from the memory, transmitting, by the electronic device, a refresh command to the memory after delaying by an offset of the transmission delay time based on a refresh interval corresponding to the second refresh period.

In accordance with another aspect of the disclosure, a method of operating an electronic device is provided. The method includes determining, by the electronic device, a first transmission delay time based on a refresh interval (tREFI) corresponding to a first refresh period outputted from memory, applying, by the electronic device, the first transmission delay time to the refresh interval, when a second refresh period is outputted from the memory, transmitting, by the electronic device, a first refresh command to the memory after delaying by an offset of the first transmission delay time based on a refresh interval corresponding to the second refresh period, and when a predetermined time expires after the first transmission delay time is determined, displaying, by the electronic device, a user interface that induces updating of the first transmission delay time to a second transmission delay time.

A memory system according to various embodiments of the disclosure decreases the number of times of transmission of a refresh command by applying an offset to a command interval, and thus, the efficiency of power of a memory device is prevented from being reduced.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram illustrating an electronic device in a network environment according to an embodiment of the disclosure;

FIG. 2 is a diagram illustrating a configuration of a memory system according to an embodiment of the disclosure;

FIG. 3 is a diagram illustrating a configuration of a memory device according to an embodiment of the disclosure;

FIG. 4 is a diagram illustrating a memory cell array according to an embodiment of the disclosure;

FIG. 5 is a diagram illustrating a refresh multiplier of a memory device according to an embodiment of the disclosure;

FIG. 6 is a diagram illustrating a register according to an embodiment of the disclosure;

FIG. 7 is a diagram illustrating performance of a memory device associated with leakage charges according to an embodiment of the disclosure;

FIG. 8 is a diagram illustrating an operation in which a host applies an offset to a command interval according to an embodiment of the disclosure;

FIG. 9 is a diagram illustrating an operation of determining an offset to be applied to a command interval according to an embodiment of the disclosure;

FIG. 10 is a diagram illustrating a time to determine an offset applied to a command interval according to an embodiment of the disclosure;

FIG. 11 is a flowchart illustrating an operation of a memory system according to an embodiment of the disclosure;

FIG. 12 is a flowchart illustrating an operation in which a memory system determines a transmission delay time according to an embodiment of the disclosure;

FIG. 13 is a diagram illustrating a user interface which induces reset of a command interval according to an embodiment of the disclosure; and

FIG. 14 is a diagram illustrating a user interface which induces automatic reset of a command interval according to an embodiment of the disclosure.

Throughout drawings, it should be noted that like reference numbers are used to depict the same or similar elements, features, and structures.

### DETAILED DESCRIPTION

The following description with reference to accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications, of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

It should be appreciated that the blocks in each flowchart and combinations of the flowcharts may be performed by one or more computer programs which include computer-executable instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g., a central processing unit (CPU)), a communication processor (CP, e.g., a modem), a graphical processing unit (GPU), a neural processing unit (NPU)(e.g., an artificial intelligence (AI) chip), a wireless-fidelity (Wi-Fi) chip, a Bluetooth™ chip, a global positioning system (GPS) chip, a near field communication (NFC) chip, connectivity chips, a sensor controller, a touch controller, a finger-print sensor controller, a display drive integrated circuit (IC), an audio CODEC chip, a universal serial bus (USB) controller, a camera controller, an image processing IC, a microprocessor unit (MPU), a system on chip (SoC), an IC, or the like.

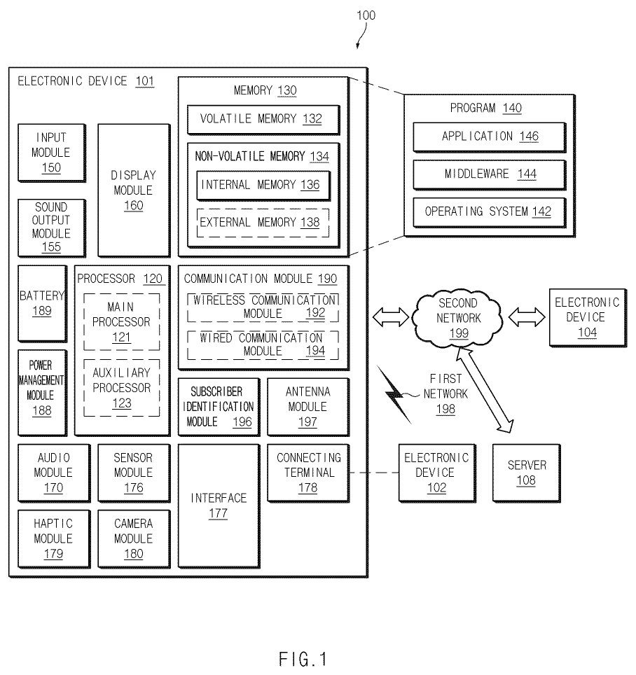

FIG. 1 is a block diagram of an electronic device in a network environment according to an embodiment of the disclosure.

Referring to FIG. 1, an electronic device 101 in an environment information 100 may communicate with an external electronic device 102 over a first network 198 (e.g., a short range wireless communication network) or may communicate with at least one of an external electronic device 104 or a server 108 over a second network 199 (e.g., a long distance wireless communication network). According to an embodiment of the disclosure, the electronic device 101 may communicate with the external electronic device 104 through the server 108. According to an embodiment of the disclosure, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module 196, or an antenna module 197. In any embodiment of the disclosure, the electronic device 101 may not include at least one (e.g., the connecting terminal 178) of the above-described components or may further include one or more other components. In some embodiments of the disclosure, some (e.g., the sensor module 176, the camera module 180, or the antenna module 197) of these components may be integrated into a single component (e.g., the display module 160).

For example, the processor 120 may execute software (e.g., a program 140) to control at least another component (e.g., hardware or software component) of the electronic device 101 connected to the processor 120, and may process and calculate various types of data. According to an embodiment of the disclosure, as at least part of data processing or calculation, the processor 120 may store instructions or data received from other components (e.g., the sensor module 176 or the communication module 190) into volatile memory 132, may process instructions or data stored in the volatile memory 132, and may store the result data in non-volatile memory 134. According to an embodiment of the disclosure, the processor 120 may include a main processor 121 (e.g., a central processing unit or an application processor) and an auxiliary processor 123 (e.g., a graphic processing unit, a neural processing unit (NPU), an image signal processor, a sensor hub processor, or a communication processor) capable of operating independently or together with the main processor. For example, when the electronic device 101 includes the main processor 121 and the auxiliary processor 123, the auxiliary processor 123 may be configured to use less power than the main processor 121 or to be specialized for a specified function. The auxiliary processor 123 may be implemented separately from the main processor 121 or as part of the main processor 121.

For example, the auxiliary processor 123 may control at least part of the functions or states associated with at least one (e.g., the display module 160, the sensor module 176, or the communication module 190) of the components of the electronic device 101, instead of the main processor 121 while the main processor 121 is in an inactive (e.g., a sleep) state or together with the main processor 121 while the main processor 121 is in an active (e.g., the execution of an application) state. According to an embodiment of the disclosure, the auxiliary processor 123 (e.g., an image signal processor or a communication processor) may be implemented as a part of operatively associated other components (e.g., the camera module 180 or the communication module 190). According to an embodiment of the disclosure, the auxiliary processor 123 (e.g., a neural network processing unit) may include a hardware structure specialized to process an artificial intelligence model. The artificial intelligence model may be generated through machine learning. For example, the learning may be performed in the electronic device 101, in which an artificial intelligence model is performed, or may be performed through a separate server (e.g., the server 108). For example, the learning algorithm may include supervised learning, unsupervised learning, semi-supervised learning, or reinforcement learning, but is not limited to the above example. The artificial intelligence model may include a plurality of artificial neural network layers. The artificial neural network may be one of a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, or a combination of two or more of the networks, but may not be limited to the above-described example. In addition to a hardware structure, additionally or alternatively, the artificial intelligence model may include a software structure.

The memory 130 may store various pieces of data used by at least one component (e.g., the processor 120 or the sensor module 176) of the electronic device 101. For example, data may include software (e.g., the program 140) and input data or output data for instructions associated with the software. The memory 130 may include the volatile memory 132 or the non-volatile memory 134.

The program 140 may be stored in the memory 130 as software, and may include, for example, an operating system 142, a middleware 144, or an application 146.

The input module 150 may receive instructions or data to be used for the component (e.g., the processor 120) of electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output a sound signal to the outside of the electronic device 101. The sound output module 155 may include, for example, a speaker or a receiver. The speaker may be used for a general purpose, such as multimedia play or recording play. The receiver may be used to receive an incoming call. According to an embodiment of the disclosure, the receiver may be implemented separately from the speaker or may be implemented as a part of the speaker.

The display module 160 may visually provide information to the outside (e.g., the user) of the electronic device 101. The display module 160 may include, for example, a display, a hologram device, or a control circuit for controlling a projector and a corresponding device. According to an embodiment of the disclosure, the display module 160 may include a touch sensor configured to sense a touch, or a pressure sensor configured to measure the strength of force generated by the touch.

The audio module 170 may convert sound to an electrical signal, or reversely, may convert an electrical signal to sound. According to an embodiment of the disclosure, the audio module 170 may obtain sound through the input module 150, or may output sound through the sound output module 155, or through an external electronic device (e.g., the external electronic device 102, a speaker, or a headphone) directly or wirelessly connected with the electronic device 101.

The sensor module 176 may sense an operation state (e.g., power or a temperature) of the electronic device 101 or an external environment state (e.g., a user state), and may generate an electrical signal or a data value corresponding the sensed state. According to an embodiment of the disclosure, the sensor module 176 may include, for example, a gesture sensor, a gyro sensor, a barometric pressure sensor, a magnetic sensor, an acceleration sensor, a grip sensor, a proximity sensor, a color sensor, an infrared (IR) sensor, a biometric sensor, a temperature sensor, a humidity sensor, or an illumination sensor.

The interface 177 may support one or more specified protocols that may be used to directly and wirelessly connect the electronic device 101 with an external electronic device (e.g., the external electronic device 102). According to an embodiment of the disclosure, the interface 177 may include, for example, an HDMI (high-definition multimedia interface), a USB (universal serial bus) interface, an SD card interface, or an audio interface.

The connecting terminal 178 may include a connector that may allow the electronic device 101 to be physically connected with an external electronic device (e.g., the external electronic device 102). According to an embodiment of the disclosure, the connecting terminal 178 may include, for example, a HDMI connector, an USB connector, an SD card connector, or an audio connector (e.g., a headphone connector).

The haptic module 179 may convert an electrical signal to a mechanical stimulation (e.g., vibration or movement) or an electrical stimulation which the user may perceive through the sense of touch or the sense of movement. According to an embodiment of the disclosure, the haptic module 179 may include, for example, a motor, a piezoelectric sensor, or an electrical stimulation device.

The camera module 180 may shoot a still image or a video image. According to an embodiment of the disclosure, the camera module 180 may include one or more lenses, image sensors, image signal processors, or flashes (or electrical flashes).

The power management module 188 may manage the power which is supplied to the electronic device 101. According to an embodiment of the disclosure, the power management module 188 may be implemented, for example, as at least part of a power management integrated circuit (PMIC).

The battery 189 may power at least one component of the electronic device 101. According to an embodiment of the disclosure, the battery 189 may include, for example, a primary cell not rechargeable, a secondary cell rechargeable, or a fuel cell.

The communication module 190 may establish a direct (or wired) communication channel or a wireless communication channel between the electronic device 101 and an external electronic device (e.g., the external electronic device 102, the external electronic device 104, or the server 108) and may perform communication through the established communication channel. The communication module 190 may include one or more communication processors which are operated independently of the processor 120 (e.g., an application processor) and support direct (or wired) communication or wireless communication. According to an embodiment of the disclosure, the communication module 190 may include a wireless communication module 192 (e.g., a cellular communication module, a short range wireless communication module, or a global navigation satellite system (GNSS) communication module) or a wired communication module 194 (e.g., a local area network (LAN) communication module or a power line communication module). The corresponding communication module among these communication modules may communicate with an external electronic device 104 through a first network 198 (e.g., a short-range communication network, such as Bluetooth, wireless fidelity (WiFi) direct or infrared data association (IrDA)) or a second network 199 (e.g., long-range wireless communication network, such as a legacy cellular network, fifth-generation (5G) networks, next-generation communication networks, Internet, or computer networks (e.g., LAN or wide area network (WAN))). The above-described kinds of communication modules may be integrated in one component (e.g., a single chip) or may be implemented with a plurality of components (e.g., a plurality of chips) which are independent of each other. The wireless communication module 192 may identify or authenticate the electronic device 101 within a communication network, such as the first network 198 or the second network 199, by using subscriber information (e.g., international mobile subscriber identity (IMSI)) stored in the subscriber identification module 196.

The wireless communication module 192 may support a 5G network and a next-generation communication technology after a fourth-generation (4G) network, for example, a new radio (NR) access technology. The NR access technology may support enhanced mobile broadband (eMBB), massive machine type communications (mMTC), or ultra-reliable and low-latency communications (URLLC). For example, the wireless communication module 192 may support a high frequency band (e.g., millimeter wave (mmWave) band) to achieve a high data transfer rate. The wireless communication module 192 may support various technologies for securing performance in a high frequency band, for example, technologies, such as beamforming, massive multiple-input and multiple-output (massive MIMO), full dimensional MIMO (FD-MIMO), an array antenna, analog beam-forming, and a large scale antenna. The wireless communication module 192 may support various requirements regulated in the electronic device 101, an external electronic device (e.g., the external electronic device 104) or a network system (e.g., the second network 199). According to an embodiment of the disclosure, the wireless communication module 192 may support peak data rate (e.g., 20 Gbps or more) for eMBB implementation, loss coverage (e.g., 164 dB or less) for mMTC implementation, or U-plane latency (e.g., downlink (DL) of 0.5 ms or less and uplink (UL) of 0.5 ms or less, or round trip of 1 ms or less) for URLLC implementation.

The antenna module 197 may transmit a signal or a power to the outside (e.g., an external electronic device) or may receive a signal or a power from the outside. According to an embodiment of the disclosure, the antenna module 197 may include an antenna including a radiator formed of a conductor or a conductive pattern formed on a substrate (e.g., a printed circuit board (PCB)). According to one embodiment of the disclosure, the antenna module 197 may include a plurality of antennas (e.g., an array antenna). In this case, at least one antenna suitable for a communication scheme used in a communication network, such as the first network 198 or the second network 199 may be selected, for example, by the communication module 190 from the plurality of antennas. The signal or power may be exchanged between the communication module 190 and an external electronic device through the selected at least one antenna or may be received from the external electronic device through the selected at least one antenna and the communication module 190. According to some embodiments of the disclosure, other parts (e.g., radio frequency integrated circuit (RFIC)) may be additionally formed as a part of the antenna module 197 in addition to the radiator.

According to various embodiments of the disclosure, the antenna module 197 may form an mmWave antenna module. According to an embodiment of the disclosure, the mmWave antenna module may include a printed circuit board (PCB), a radio frequency integrated circuit (RFIC), and a plurality of antennas (e.g., an array antenna). The RFIC may be disposed on or adjacent to a first surface (e.g., a bottom surface) of the PCB and may support a specified high frequency band (e.g., mmWave band). The plurality of antennas may be disposed on or adjacent to a second surface (e.g., a top surface or a side surface) of the PCB and may transmit or receive a signal in the specified high frequency band.

At least some of the components may be connected to each other through a communication scheme (e.g., a bus, a general purpose input and output (GPIO), a serial peripheral interface (SPI), or a mobile industry processor interface (MIPI)) between peripheral devices and may exchange signals (e.g., commands or data) with each other.

According to an embodiment of the disclosure, the command or data may be transmitted or received between the electronic device 101 and the external electronic device 104 through the server 108 connected to the second network 199. Each of the external electronic device 102 or 104 may be a device of which the type is the same as or different from that of the electronic device 101. According to an embodiment of the disclosure, all or a part of operations to be executed by the electronic device 101 may be executed in one or more external electronic devices among the external electronic devices 102 or 104, or the server 108. For example, when the electronic device 101 needs to perform any function or service automatically or in response to a request from the user or any other device, the electronic device 101 may additionally request one or more external electronic devices to perform at least part of the function or service, instead of internally executing the function or service. The one or more external electronic devices which receive the request may execute at least a part of the function or service thus requested or an additional function or service associated with the request, and may provide a result of the execution to the electronic device 101. The electronic device 101 may process the result as it is or additionally, and may provide a result of the processing as at least a part of the response to the request. To this end, for example, cloud computing, distributed computing, mobile edge computing (MEC), or client-server computing may be used. For example, the electronic device 101 may provide an ultra-low latency service by using distributed computing or mobile edge computing. In another embodiment of the disclosure, the external electronic device 104 may include an Internet of Things (IoT) device. The server 108 may be an intelligent server using machine learning and/or a neural network. According to an embodiment of the disclosure, the external electronic device 104 or the server 108 may be included in the second network 199. The electronic device 101 may be applied to an intelligent service (e.g., a smart home, a smart city, a smart car, or a healthcare) based on 5G communication technology and IoT-related technology.

The electronic device 101 according to various embodiments disclosed in the specification may be implemented with various types of devices. The electronic device 101 may include, for example, a portable communication device (e.g., a smartphone), a computer device, a portable multimedia device, a mobile medical appliance, a camera, a wearable device, or a home appliance. The electronic device 101 according to an embodiment of this specification may not be limited to the above-described devices.

Various embodiments of the disclosure and terms used herein are not intended to limit the technical features described in the disclosure to specific embodiments of the disclosure, and it should be understood that the embodiments and the terms include modification, equivalent, or alternative on the corresponding embodiments described herein. With regard to description of drawings, similar or related components may be marked by similar reference marks/numerals. The singular form of the noun corresponding to an item may include one or more of items, unless interpreted otherwise in context. In the disclosure, the expressions “A or B”, “at least one of A and B”, “at least one of A or B”, “A, B, or C”, “at least one of A, B, and C”, and “at least one of A, B, or C” may include any and all combinations of one or more of the associated listed items. The terms, such as “first” or “second” may be used to simply distinguish the corresponding component from the other component, but do not limit the corresponding components in other aspects (e.g., importance or order). When a component (e.g., a first component) is referred to as being “coupled with/to” or “connected to” another component (e.g., a second component) with or without the term of “operatively” or “communicatively”, it may mean that a component is connectable to the other component, directly (e.g., by wire), wirelessly, or through the third component.

In various embodiments of the disclosure, the term “module” used herein may include a unit, which is implemented with hardware, software, or firmware, and may be interchangeably used with the terms “logic”, “logical block”, “part”, or “circuit”. The “module” may be a minimum unit of an integrated part or may be a minimum unit of the part for performing one or more functions or a part thereof. For example, according to an embodiment of the disclosure, the module may be implemented in the form of an application-specific integrated circuit (ASIC).

Various embodiments of the disclosure may be implemented with software (e.g., program 140) including one or more instructions stored in a storage medium (e.g., embedded memory 136 or external memory 138) readable by a machine (e.g., the electronic device 101). For example, the processor (e.g., the processor 120) of the machine (e.g., the electronic device 101) may call at least one instruction of the stored one or more instructions from a storage medium and then may execute the at least one instruction. This enables the machine to operate to perform at least one function depending on the called at least one instruction. The one or more instructions may include a code generated by a complier or a code executable by an interpreter. The machine-readable storage medium may be provided in the form of a non-transitory storage medium. Herein, ‘non-transitory’ just means that the storage medium is a tangible device and does not include a signal (e.g., electromagnetic waves), and this term does not distinguish between the case where data is semi-permanently stored in the storage medium and the case where the data is stored temporarily.

According to an embodiment of the disclosure, a method according to various embodiments disclosed herein may be provided to be included in a computer program product. The computer program product may be traded between a seller and a buyer as a product. The computer program product may be distributed in the form of a machine-readable storage medium (e.g., compact disc read only memory (CD-ROM)) or may be distributed (e.g., downloaded or uploaded), through an application store (e.g., PlayStore™), directly between two user devices (e.g., smartphones), or online. In the case of on-line distribution, at least part of the computer program product may be at least temporarily stored in the machine-readable storage medium, such as the memory of a manufacturer's server, an application store's server, or a relay server or may be generated temporarily.

According to various embodiments of the disclosure, each component (e.g., a module or a program) of the above-described components may include a single entity or a plurality of entities, and some of the plurality of objects may be separately arranged on other components. According to various embodiments of the disclosure, one or more components of the above-described components or operations may be omitted, or one or more other components or operations may be added. Alternatively or additionally, a plurality of components (e.g., a module or a program) may be integrated into one component. In this case, the integrated component may perform one or more functions of each component of the plurality of components in the manner same as or similar to being performed by the corresponding component of the plurality of components prior to the integration. According to various embodiments of the disclosure, operations executed by modules, programs, or other components may be executed by a successive method, a parallel method, a repeated method, or a heuristic method. Alternatively, at least one or more of the operations may be executed in another order or may be omitted, or one or more operations may be added.

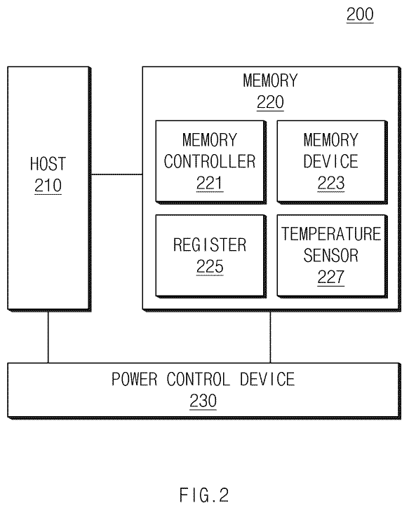

A memory system 200 for reducing power consumption according to a refresh operation to be described with reference to the following drawings may be a part of the electronic device 101 described above. Also, at least one embodiment among various embodiments described with reference to FIGS. 2 to 14 may be combined with any other embodiment.

FIG. 2 is a diagram illustrating a configuration of the memory system 200, according to an embodiment of the disclosure.

Referring to FIG. 2, the memory system 200 according to various embodiments may include a host 210 (e.g., the processor 120), memory 220 (e.g., the memory 130), and power control device 230 (e.g., the power management module 188).

According to various embodiments of the disclosure, the host 210 may communicate with the memory 220 based on various interface protocols. According to an embodiment of the disclosure, the various interface protocols may be one of peripheral component interconnect—express (PCI-E), advanced technology attachment (ATA), serial ATA (SATA), parallel ATA (PATA), or serial attached SCSI (SAS). However, this is only an example, and various embodiments are not limited thereto. For example, the interface protocol between the host 210 and the memory 220 may include any other interface, such as universal serial bus (USB), multi-media card (MMC), enhanced small disk interface (ESDI), or integrated drive electronics (IDE).

According to various embodiments of the disclosure, the power control device 230 may supply a power necessary for various components of the memory system 200. According to an embodiment of the disclosure, the power control device 230 may control the power supply to the memory 220.

According to various embodiments of the disclosure, the memory 220 may be a storage device which is composed of semiconductor elements.

According to an embodiment of the disclosure, the memory 220 may be memory (e.g., the volatile memory 132) which stores data only while the power is supplied thereto. For example, the memory 220 may include at least one of DRAM, synchronous DRAM (SDRAM), double data rate SDRAM (DDR SDRAM), low power double data rate SDRAM (LPDDR SDRAM), or graphics double data rate SDRAM (GDDR SDRAM). However, a memory device 223 according to various embodiments is not limited to the above example.

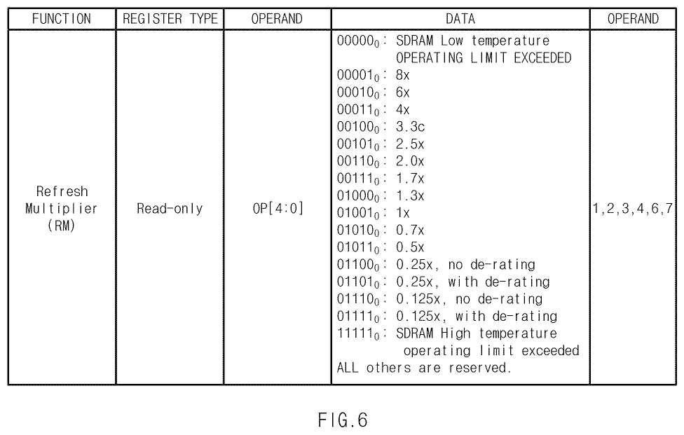

According to an embodiment of the disclosure, the memory 220 may perform an operation corresponding to a control command received from the host 210. For example, the control command may be associated with at least one of an active operation, a write operation, a read operation, or a precharge operation. However, this is only an example, and various embodiments are not limited thereto. For example, a refresh command to be described with reference to FIG. 6 may correspond to the control command.

According to an embodiment of the disclosure, the memory 220 may include a memory controller 221, the memory device 223, a register 225, and a temperature sensor 227.

According to various embodiments of the disclosure, the memory controller 221 may control all operations of the memory 220. According to an embodiment of the disclosure, the memory controller 221 may control the data exchange between the host 210 and the memory 220. For example, the memory controller 221 may control the memory device 223 depending on the control command received from the host 210.

According to various embodiments of the disclosure, the memory device 223 may store data under control of the memory controller 221.

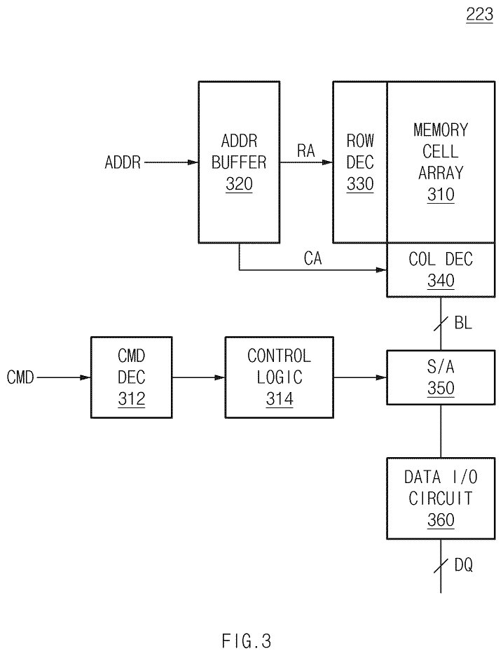

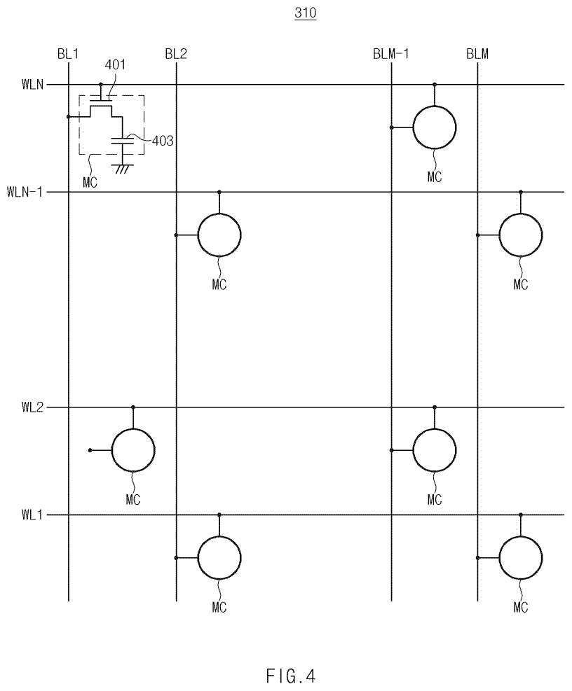

The memory device 223 will be described in detail with reference to FIGS. 3 and 4.

FIG. 3 is a diagram illustrating a configuration of the memory device 223, according to an embodiment of the disclosure.

FIG. 4 is a diagram illustrating a memory cell array 310, according to an embodiment of the disclosure.

Referring to FIG. 3, the memory device 223 according to various embodiments may include the memory cell array 310, an address buffer (ADDR BUFFER) 320, row decoder (ROW DEC) 330, column decoder (COL DEC) 340, command decoder (CMD DEC) 312, control logic 314, a sense amplifier (S/A) unit 350, and a data input/output (I/O) circuit 360.

According to various embodiments of the disclosure, the memory cell array 310 may include a plurality of memory cells MC where data are stored. Referring to FIG. 4, the plurality of memory cells MC may be provided in the form of a matrix with rows and columns. In this regard, the memory cell array 310 may include a plurality of word lines WL and a plurality of bit lines BL which are connected to the memory cells MC. For example, the plurality of word lines WL may be connected to the rows of memory cells MC, and the plurality of bit lines BL may be connected to the columns of memory cells MC.

According to various embodiments of the disclosure, the command decoder 312 may decode a control command CMD received from the memory controller 221 such that control signals corresponding to the control command are generated by the control logic 314.

According to various embodiments of the disclosure, the control logic 314 may control operations of the memory cell array 310 based on a decoding result of the command decoder 312. According to an embodiment of the disclosure, the control logic 314 may generate a control signal associated with at least one of the active operation, the write operation, the read operation, or the precharge operation so as to be provided to the memory cell array 310.

According to various embodiments of the disclosure, the address buffer 320 may receive an address ADDR from the memory controller 221. The address ADDR may include a row address RA addressing a row of the memory cell array 310 and a column address CA addressing a column of the memory cell array 310. According to an embodiment of the disclosure, the address buffer 320 may transmit the received row address RA to the row decoder 330 and may transmit the received column address CA to the column decoder 340.

According to various embodiments of the disclosure, the row decoder 330 may select any one of the plurality of word lines WL connected to the memory cell array 310. According to an embodiment of the disclosure, by decoding the row address RA received from the address buffer 320, the row decoder 330 may select any one word line corresponding to the row address RA and may activate the selected word line.

According to various embodiments of the disclosure, the column decoder 340 may select any one of the plurality of bit lines BL of the memory cell array 310. According to an embodiment of the disclosure, the column decoder 340 may select any one corresponding to the column address CA by decoding the column address CA received from the address buffer 320.

According to various embodiments of the disclosure, the sense amplifier unit 350 may include a plurality of bit line sense amplifiers which are respectively connected to the bit lines BL of the memory cell array 310. The bit line sense amplifier may sense a voltage change of the connected bit line BL and may amplify and output a sensing result.

According to various embodiments of the disclosure, the data input/output circuit 360 may output data generated based on the voltage sensed and amplified by the sense amplifier unit 350 to the outside through data lines DQ.

As described above, the memory controller 221 may store data to the memory cell MC. The memory cell MC may include one transistor 401 and one capacitor 403.

According to an embodiment of the disclosure, when the memory controller 221 stores data “1” (or “high data”) to the memory cell MC, the memory controller 221 may apply a high potential to the memory cell MC to charge the capacitor 403 with charges. Also, when the memory controller 221 stores data “0” (or “low data”) to the memory cell MC, the memory controller 221 may apply a low potential to the memory cell MC to discharge the capacitor 403.

When the capacitor 403 of the memory cell MC is ideal, the charges stored in the capacitor 403 should be always maintained; however, because the charges stored in the capacitor 403 leak over time, the data stored in the memory cell MC may be lost.

In this regard, the memory system 200 may perform the refresh operation before the data stored in the memory cell MC are lost, and thus, it may be possible to continuously maintain the data. According to an embodiment of the disclosure, the refresh operation may be performed through the precharge operation, which is an operation of selecting and activating a row of memory cells and closing the word line again.

According to various embodiments of the disclosure, the refresh operation of the memory system 200 may be performed based on the refresh command provided by the host 210.

According to an embodiment of the disclosure, the host 210 may determine a transmission interval (or a transmission time) (hereinafter referred to as a “command interval”) of the refresh command based on a refresh multiplier (or a refresh rate) stored in the register 225 and may transmit the refresh command to the memory 220 based on the command interval. Afterwards, the memory 220 may perform the refresh operation after receiving the refresh command from the host 210. For example, the refresh multiplier to be updated in the register 225 may be associated with an internal temperature of the memory 220 (e.g., the memory device 223).

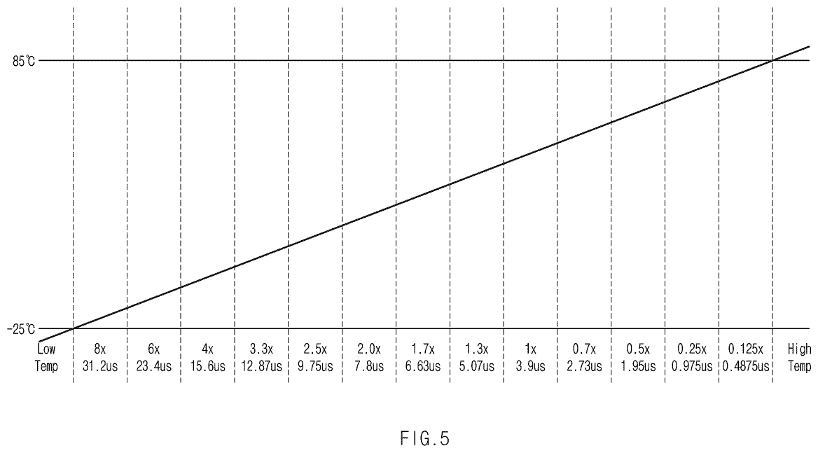

The refresh multiplier associated with the internal temperature will be described in detail with reference to FIGS. 5 and 6.

FIG. 5 is a diagram illustrating a refresh multiplier of memory device according to an embodiment of the disclosure.

FIG. 6 is a diagram illustrating a register 225 according to an embodiment of the disclosure.

Referring to FIG. 5, in the register 225, there may be updated the refresh multiplier which has a long period as the internal temperature of the memory 220 (e.g., the memory device 223) decreases, and there may be updated the refresh multiplier which has a relatively short period as the internal temperature increases.

For example, as illustrated in FIG. 5, the refresh operation may be performed at the period of approximately “31.2 μs” when the internal temperature is approximately −25° C., and the refresh operation may be specified to be performed at the period of approximately “0.4875 μs” when the internal temperature gradually increases and is then close to approximately 85° C. The above description is given based on the situation that the amount of charges leaking as the internal temperature increases also increases. However, this is only an example, and various embodiments are not limited thereto. For example, in the register 225, there may be updated the refresh multiplier which has a short period as the internal temperature decreases, and there may be updated the refresh multiplier which is specified regardless of the internal temperature. Also, numerical values of the internal temperature and the refresh multiplier illustrated in FIG. 5 are provided according to an embodiment of the disclosure, and various embodiments are not limited thereto.

According to an embodiment of the disclosure, the register 225 may include mode register 4 (hereinafter referred to as an “MR4”) defined by the joint electron device engineering council (JEDEC) standard. For example, referring to FIG. 6, OP[4:0] of the operand of the MR4 may indicate the refresh multiplier according to the internal temperature.

For example, a value set in the OP[4:0] of the MR4 may indicate the refresh multiplier necessary at a current internal temperature of the memory 220. For example, referring to FIGS. 5 and 6, when the current internal temperature of the memory 220 is approximately 85° C., “0.125×” may be set in the OP[4:0] of the MR4 as a value indicating the refresh multiplier. This means that the refresh multiplier necessary at the current internal temperature is approximately “0.4875 μs”.

According to various embodiments of the disclosure, the memory controller 221 may update the refresh multiplier stored in the register 225 periodically or consistently.

In this regard, the memory controller 221 may check the refresh multiplier necessary at the current internal temperature of the memory 220 based on a reference period and may store the refresh multiplier to the register 225. The reference period may refer to information which defines the refresh multiplier of each of a plurality of temperature intervals obtained by dividing a temperature range (e.g., −25° C.~85° C.) in which the memory device 223 is capable of operating normally.

For example, the memory controller 221 may check the internal temperature of the memory 220 based on information output through the temperature sensor 227 and may obtain the refresh multiplier corresponding to the internal temperature of the memory 220 from the reference period.

A configuration where only the refresh multiplier corresponding to the current internal temperature of the memory 220 is updated in the register 225 is described above.

However, this is only an example, and various embodiments are not limited thereto. For example, the reference period by which there is defined the refresh multiplier for each of the temperature intervals obtained by dividing the temperature range in which the memory device 223 is capable of operating normally may be stored in the register 225.

In this case, the host 210 may check the internal temperature of the memory 220 based on the information output through the memory 220 (e.g., the temperature sensor 227). Also, the host 210 may transmit the refresh command based on obtaining the temperature interval corresponding to the internal temperature of the memory 220 and the refresh multiplier corresponding to the temperature interval from the reference period stored in the memory 220.

However, even though the refresh multiplier expires, the charges stored in the memory device 223 may not leak to the level causing the data loss. The refresh operation which is performed in a state where charges do not leak to the above level causing the data loss may reduce the efficiency of power of the memory device 223.

In this regard, the memory system 200 according to various embodiments may decrease the number of times of transmission of the refresh command by applying an offset (e.g., a transmission delay time) to the command interval and thus may prevent the efficiency of power of the memory device 223 from being reduced. This will be described with reference to the following drawings.

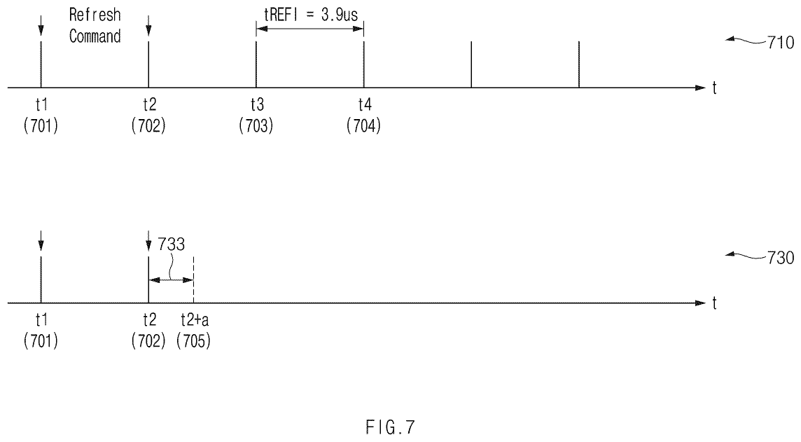

FIG. 7 is a diagram illustrating performance of memory device associated with leakage charges according to an embodiment of the disclosure.

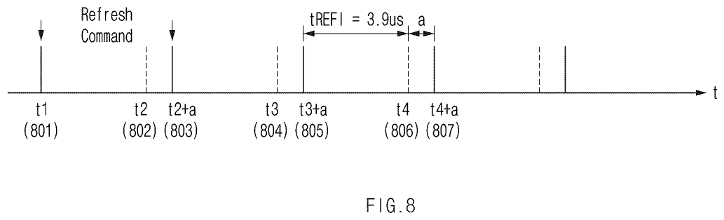

FIG. 8 is a diagram illustrating an operation in which host applies an offset to a command interval according to an embodiment of the disclosure.

As described above, the refresh multiplier (or the command interval) may be determined based on the temperature interval which is defined by the reference period.

However, the amount of charges leaking depending on a temperature change may vary depending on the performance of the memory device 223. The performance associated with the leakage charges may somewhat vary depending on a structure or a manufacturing process condition of the memory device 223.

In other words, when the performance of the memory device 223 associated with the leakage charges has a first level, the charges stored in the capacitor 403 may leak to a level causing data loss at a time (e.g., a first time t1) 701 when a predetermined refresh multiplier (e.g., 3.9 μs) expires. In this case, like 710 of FIG. 7, based on the predetermined refresh multiplier, the host 210 may transmit the refresh command to the memory 220 at a first time t1 701, a second time t2 702, a third time t3 703, and a fourth time t4 704.

However, when the performance of the memory device 223 associated with the leakage charges has a second level higher than the first level, the charges stored in the capacitor 403 may not leak to the level causing the data loss. In other words, like 730 of FIG. 7, the charges stored in the capacitor 403 may leak to the level causing the data loss at a time (e.g., a fifth time t2+a) 705 when a given time “a” passes from the time (e.g., the second time t2) 702 when the predetermined refresh multiplier expires.

As described above, the refresh operation which is performed in a state where charges do not leak to the level causing the data loss may reduce the efficiency of power of the memory device 223. According to the above description, to prevent the efficiency of power of the memory device 223 from being reduced, there is a need to perform the refresh operation in a situation where the charges leak to the level causing the data loss.

In this regard, the host 210 according to various embodiments may determine the command interval based on the refresh multiplier stored in the register 225 and may apply the offset “a” to the command interval such that the transmission time of the refresh command is delayed as much as a given time.

According to an embodiment of the disclosure, the host 210 may check a first time t1 801 to transmit a first refresh command and a second time t2 802 at which a second refresh command is to be transmitted based on a refresh interval tREFI (e.g., approximately 3.9 μs) corresponding to the refresh multiplier (or the refresh rate) stored in the register 225. In this case, the host 210 may transmit the second refresh command at a delay time “t2+a” 803, which is obtained by applying the offset “a” to the second time t2 802, without transmitting the second refresh command at the second time t2 802.

Also, the host 210 may transmit a third refresh command and a fourth refresh command at a time “t3+a” 805, which is obtained by applying the offset “a” to a third time t3 804, and a time “t4+a” 807, which is obtained by applying the offset “a” to a fourth time t4 806, without transmitting the third refresh command and the fourth refresh command at the third time t3 804 and the fourth time t4 806 checked based on the first time t1 801, at which the first refresh command is transmitted, and the refresh interval tREFI corresponding to the refresh multiplier (or the refresh rate) stored in the register 225.

In other words, the host 210 may decrease the number of times of transmission of the refresh command by delaying the transmission of the refresh command until just before the charges stored in the memory device 223 leak to the level causing the data loss.

Below, a method of determining the offset “a” to be applied to the command interval will be described.

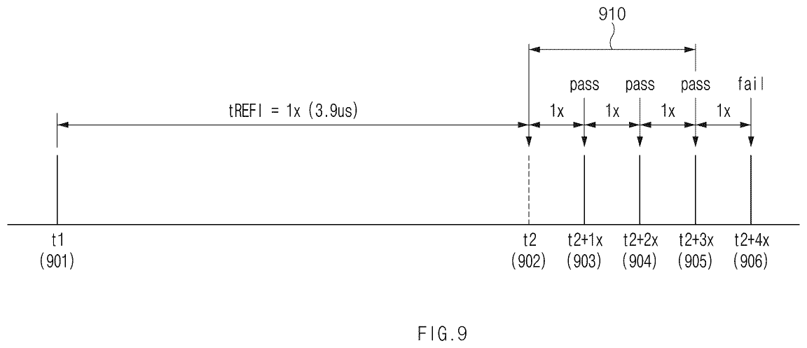

FIG. 9 is a diagram illustrating an operation of determining the offset “a” to be applied to the command interval according to an embodiment of the disclosure.

According to various embodiments of the disclosure, in determining the offset “a”, the host 210 may write a test pattern to the memory device 223. For example, the operation of writing the test pattern may include an operation of writing data “1” (or “high data”) to the memory cell MC. However, this is only an example, and various embodiments are not limited thereto. For example, data “0” (or “low data”) may be written to the memory cell MC, or the test pattern in which data “1” and data “0” are combined may be written to the memory cell MC. Also, according to an embodiment of the disclosure, the test pattern may be written to the remaining memory cells MC other than memory cells MC where a bootstrap code is stored.

According to various embodiments of the disclosure, the host 210 may perform an operation of reading the test pattern and may determine the offset “a” based on at least a portion of a read result.

According to an embodiment of the disclosure, the host 210 may determine a time during which a pattern identical to the test pattern is read (e.g., a time before a pattern different from the test pattern is read) as the offset “a”.

In this regard, referring to FIG. 9, the host 210 may determine a read time based on a second time t2 902 at which the predetermined refresh interval (e.g., approximately 3.9 μs) expires from a first time t1 901.

For example, the read time (hereinafter referred to as a “step”) of reading the test pattern may include a first read time “t2+1×” (e.g., a first step) increased from the second time t2 902 as much as a given time “x” (hereinafter referred to as a step interval of the following read times) (e.g., approximately 0.3 μs), a second read time “t2+2x” 903 (e.g., a second step) increased from the first read time as much as the given time “x”, a third read time “t2+3x” 905 (e.g., a third step) increased from the second read time “t2+2x” 904 as much as the given time, and a fourth read time “t2+4x” 906 (e.g., a fourth step) increased from the third read time “t2+3x” 905 as much as the given time.

For example, after a pattern identical to the test pattern is checked until the third read time, when a pattern different from the test pattern is checked at the fourth read time “t2+4x” 906 (e.g., the fourth step), the host 210 may determine a time 910 (e.g., 0.45 μs (=0.15 μs*third step)) from the second time t2 to the third read time “t2+3x” 905 as an offset.

According to various embodiments of the disclosure, the host 210 may apply the determined offset to the refresh interval corresponding to the refresh multiplier. For example, the refresh interval to which the offset is applied may be a time from the first time t1 901 to the third read time “t2+3x” 905 (e.g., 4.35 μs (=3.9 μs+0.45 μs)).

According to an embodiment of the disclosure, the host 210 may apply the offset to the refresh interval tREFI corresponding to the refresh multiplier (or the refresh rate) stored in the register 225. For example, the host 210 may generate the refresh interval, to which the offset is applied, by testing and calculating the refresh interval corresponding to each refresh multiplier based on each of refresh multipliers (e.g., a first refresh multiplier to an n-*fi refresh multiplier) stored in the register 225. Also, the host 210 may store the offset, which is applied to the refresh interval corresponding to each refresh multiplier stored in the register 225, (or the refresh interval to which the offset is applied) in a separate storage space (e.g., the non-volatile memory 134). In this case, even after the rebooting operation of the electronic device 101, the host 210 may transmit the refresh command based on the data stored in the separate storage space (e.g., the non-volatile memory 134).

According to an embodiment of the disclosure, the host 210 may apply the offset at a time when the refresh multiplier stored in the non-volatile memory 134 expires and may check the refresh interval. For example, when the first refresh multiplier is output from the register 225, the host 210 may transmit the refresh command based on the refresh interval corresponding to the second refresh multiplier delayed from the first refresh multiplier as much as the offset.

As described above, to read the test pattern, the host 210 may perform the operation of reading all the memory cells MC while increasing the read time step by step based on the second time t2 902. For example, the step interval of the read time may be specified for each refresh interval. For example, in the case of the first refresh interval (e.g., approximately 3.9 μs), the step interval of the read time may be specified as approximately 0.3 μs; in the case of the second refresh interval (e.g., approximately 1.95 μs), the step interval of the read time may be specified as approximately 0.15 μs. However, this is only an example, and various embodiments are not limited thereto. For example, the step interval of the read time may have a period longer or shorter than the above period, depending on the status of the electronic device 101.

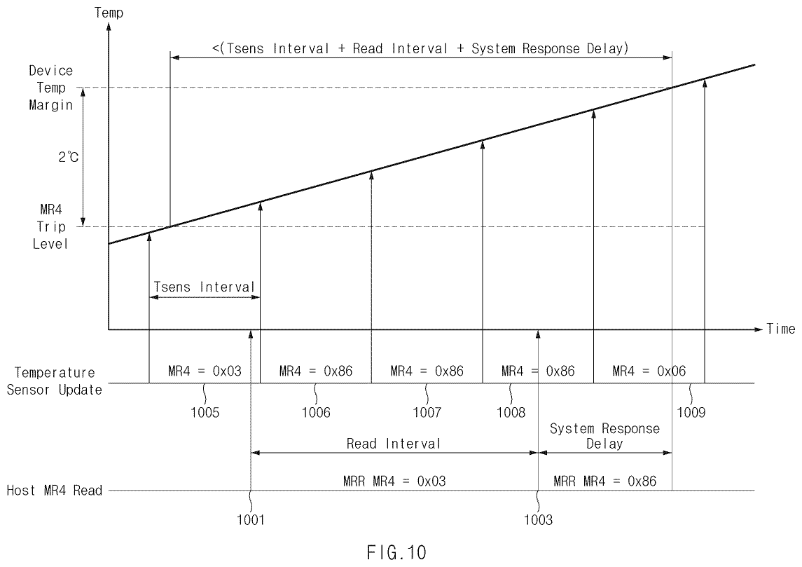

FIG. 10 is a diagram illustrating a time to determine offset “a” to be applied to a command interval according to an embodiment of the disclosure.

Prior to the description, an “MR4 Trip Level” illustrated in FIG. 10 may mean a point where the MR4 refresh multiplier changes (e.g., an MR4 change from 0x03 to 0x86), a “Device Temp Margin” may mean the maximum temperature margin (e.g., approximately ≥2° C.) between the MR4 trip and a time when an actual MR4 value reaches the host 210, and a “System Response delay” may mean a delay until the actual MR4 value is updated in the host 210 after the MR4 read command. Also, a “Tsense interval” may mean an MR4 register value update interval tTSI, a “Read interval” may mean a period at which the host 210 sends the MR4 read command to the memory 220 (e.g., a DRAM), and a “<(Tsens Interval+Read Interval+System Response Delay)” may be a total sum of the tTSI, the Read interval, and the System Response Delay and may satisfy the following condition.

$$TempGradient \times ( ReadInterval + tTSI + SysRespDelay ) \leq 2 ° C . \qquad Equation 1$$

In Equation 1 above, the “TempGradient” may indicate a maximum temperature change gradient which the memory 220 experiences an interesting temperature of a 2° C. range.

Referring to FIG. 10, the memory 220 may update the refresh multiplier in the register 225 based on a predetermined MR4 register value update interval Tsens Interval. For example, a first value of 0x03 indicating the refresh multiplier may be updated based on a first update interval 1005. Also, when a second update interval 1006, a third update interval 1007, and a fourth update interval 1008 arrive, a second value of 0x86, a third value of 0x86, a fourth value of 0x86, and a fifth value of 0x06 may be updated.

In addition, the host 210 may also obtain the refresh multiplier from the register 225 every predetermined read command transmission interval Read Interval and may use the refresh multiplier to determine the command interval. For example, the first value of 0x03 updated in the first update interval 1005 may be obtained in a first read command transmission interval 1001, and the fourth value of 0x86 updated in the fourth update interval 1008 may be obtained in a second read command transmission interval 1003.

However, as soon as the first value is obtained in the first read command transmission interval 1001, the internal temperature of the memory 220 may be changed; in this case, an actual refresh multiplier may be changed from the first value to the second value. In other words, when the temperature of the memory 220 frequently changes, the refresh multiplier by the host 210 may be different from the current refresh multiplier updated in the register 225.

Accordingly, the host 210 according to various embodiments of the disclosure may determine the offset “a” in a situation where the temperature change of the memory 220 is not frequent. For example, the situation where the temperature change of the memory 220 is not frequent may be a situation where the refresh multipliers of the same value are continuously obtained through the register 225.

The memory system 200 described above is an embodiment of the disclosure, and various embodiments are not limited thereto. For example, at least one of the components of the memory system 200 according to various embodiments may be omitted or one or more other components may be added as components of the memory system 200. In addition, at least one of the above components may be integrated with any other component. For example, according to an embodiment of the disclosure, the register 225 may be integrated with the memory controller 221 and/or the memory device 223.

In addition, the electronic device 101 including the memory system 200 according to various embodiments may output a user interface (or a user interface which induces a reset of the command interval) which induces a reset of the command interval (e.g., the refresh multiplier or the offset) at a predetermined time (e.g., one year) periodically. For example, the operation of determining the offset (e.g., the transmission delay time) described above through FIGS. 7 to 10 may be performed in the first booting operation (e.g., a booting operation performed for the first time after manufacturing) of the electronic device 101, and the electronic device 101 may determine a new offset together with a rebooting operation based on an input to the user interface after the first booting operation.

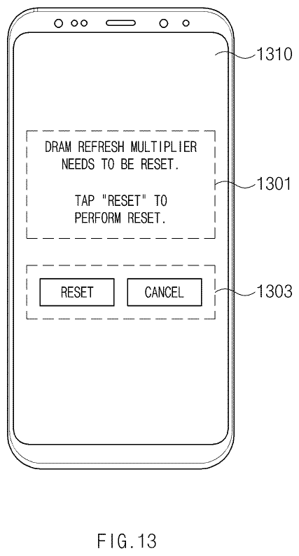

FIG. 13 is a diagram illustrating a user interface which induces reset of a command interval according to an embodiment of the disclosure.

Referring to FIG. 13, a user interface 1310 for resetting the command interval may include information 1301 guiding that the reset of the command interval is required and an item 1303 receiving a user input associated with the reset or cancel of the command interval.

In this regard, when the user input associated with the reset of the command interval is received, the electronic device 101 may perform an operation of applying a new offset to the refresh interval. For example, the electronic device 101 may store the new offset to the memory 130 (e.g., the non-volatile memory 134) and may use the new offset to transmit the refresh command.

Additionally or selectively, it may be possible to reset the command interval (e.g., the refresh multiplier or the offset) automatically (or regardless of the user input) at a predetermined time (e.g., one year) periodically.

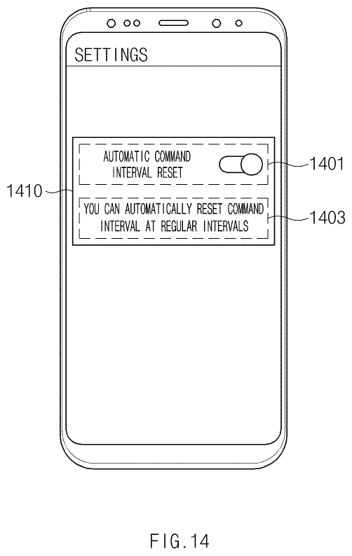

FIG. 14 is a diagram illustrating a user interface which induces automatic reset of a command interval according to an embodiment of the disclosure.

Referring FIG. 14, the electronic device 101 may provide a user interface 1410 for enabling or disabling a function of automatically resetting the command interval, as illustrated in FIG. 14. According to an embodiment of the disclosure, the user interface 1410 may include an item 1401 receiving the user input associated with the enable or disable of the function for automatically resetting the command interval and information (e.g., description) 1403 about the function for inducing the automatic reset of the command interval.

For example, when a function of automatically resetting a command interval is activated, the electronic device 101 may automatically reset a command interval at a predetermined time periodically.

For example, when the function of inducing the automatic reset of the command interval is disabled, the electronic device 101 may output a user interface (e.g., the user interface 1310 of FIG. 13) for inducing the reset of the command interval every predetermined time periodically. According to an embodiment of the disclosure, even though the predetermined time arrives, the electronic device 101 may omit the operation of outputting the user interface for inducing the reset of the command interval.

However, this is only an example, and various embodiments are not limited thereto. For example, the electronic device 101 may perform an operation of determining a new offset together with the rebooting operation at the predetermined time periodically, regardless of the enable of the function inducting the automatic reset of the command interval. Also, the electronic device 101 may determine a new offset whenever the rebooting operation is performed, regardless of the enable of the function which induces the automatic reset of the command interval.

According to various embodiments of the disclosure, an electronic device 101 may include a display module 160, memory 130 that stores a refresh period, and a processor 120. The processor 120 may determine a first transmission delay time based on a refresh interval (tREFI) corresponding to a first refresh period outputted from the memory 130, may apply the first transmission delay time to the refresh interval, may transmit a first refresh command to the memory 130 after a delay corresponding to an offset of the first transmission delay time based on a refresh interval (tREFI) corresponding to a second refresh period, when the second refresh period is outputted from the memory 130, and may display a user interface that induces updating of the first transmission delay time to a second transmission delay time through the display module 160 (or a user interface that induces updating of the first transmission delay time to the second transmission delay time), when a predetermined time expires after the first transmission delay time is determined.

According to various embodiments of the disclosure, in determining the first transmission delay time, the processor 120 may write a test pattern to the memory 130, to perform a read operation on the memory 130 based on the refresh interval (tREFI) corresponding to the first refresh period, at each test period that increases by specific time intervals, and may determine the first transmission delay time based on a time at which a pattern identical to the test pattern is read.

According to various embodiments of the disclosure, the processor 120 may determine the second transmission delay time based on a refresh interval (tREFI) corresponding to a third refresh period outputted from the memory 130, in response to receiving an input indicating the update of the first transmission delay time to the second transmission delay time, may apply the second transmission delay time to the refresh interval, and may transmit a second refresh command to the memory 130 after a delay corresponding to an offset of the second transmission delay time based on a refresh interval (tREFI) corresponding to a fourth refresh period, when the fourth refresh period is outputted from the memory 130.

According to various embodiments of the disclosure, in determining the second transmission delay time, the processor 120 may write a test pattern to the memory 130, to perform a read operation on the memory 130 at each test period that increases by a specific time interval based on the refresh interval (tREFI) corresponding to the third refresh period, and may determine the second transmission delay time based on a time during which a pattern identical to the test pattern is read.

According to various embodiments of the disclosure, a memory system 200 may include volatile memory 132 that includes a memory controller 221 outputting a refresh period, and a processor 120 that is operatively connected with the volatile memory 132. The processor 120 may determine a transmission delay time (a) based on a refresh interval (tREFI) corresponding to a first refresh period outputted from the memory controller 221, may apply the transmission delay time (a) to the refresh interval, and may transmit a refresh command to the volatile memory 132 after a delay corresponding to an offset of the transmission delay time (a) based on a refresh interval (tREFI) corresponding to a second refresh period, when the second refresh period is outputted from the memory controller 221.

According to various embodiments of the disclosure, in determining the transmission delay time, the processor 120 may write a test pattern to the volatile memory 132, may perform a read operation on the volatile memory 132 at each test period that increases by specific time intervals based on the refresh interval (tREFI) corresponding to the first refresh period, and may determine the transmission delay time based on a time during which a pattern identical to the test pattern is read.

According to various embodiments of the disclosure, the memory system 200 may include a register 225 that updates the refresh period based on a specific period, and the processor 120 may store the second refresh period, to which the transmission delay time (a) is applied, to the register 225.

According to various embodiments of the disclosure, the register 225 may update the refresh period corresponding to an internal temperature of the volatile memory 132.

According to various embodiments of the disclosure, the processor 120 may obtain a refresh period that is repeated at a certain level from among refresh periods outputted from the memory controller 221 for a specified time, as the first refresh period.

According to various embodiments of the disclosure, the memory system 200 may further include non-volatile memory 134. The processor 120 may store the transmission delay time to the non-volatile memory 134 and to apply the transmission delay time (a) to a refresh interval (tREFI) corresponding to the refresh period outputted from the memory controller 221.

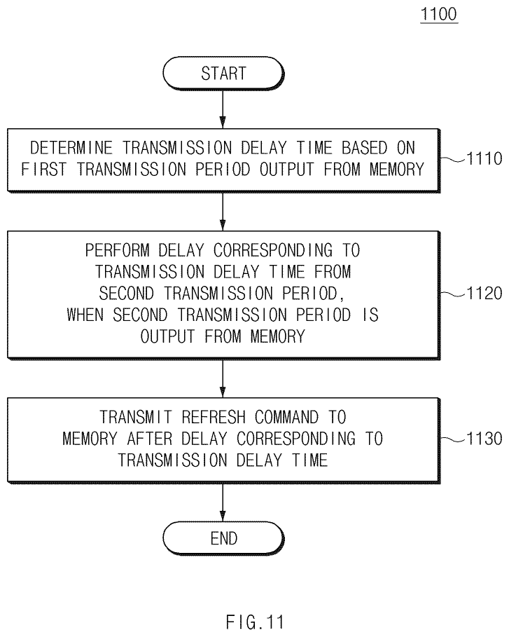

FIG. 11 is a flowchart illustrating an operation 1100 of memory system according to an embodiment of the disclosure.

Below, the description associated with FIGS. 7 and 8 may be referenced in association with an operation to be described with reference to FIG. 11. Also, in the following embodiment of the disclosure, respective operations may be sequentially performed. However, the operations are not necessarily performed sequentially. For example, the order of the respective operations may be changed, and at least two of the operations may be performed in parallel. In addition, at least one of the operations described above may be omitted depending on an embodiment.

Referring to FIG. 11, in operation 1110, the memory system 200 (e.g., the host 210) according to various embodiments may determine a transmission delay time based on a first transmission interval (or refresh multiplier) output from the memory 220. The transmission delay time may be a time elapsed from the first transmission interval until just before charges stored in the memory device 223 leak to a level causing data loss. According to an embodiment of the disclosure, the first transmission interval may be a time when the host 210 transmits a first refresh command to the memory 220. For example, the first transmission interval may be determined by the refresh multiplier stored in the register 225.

According to various embodiments of the disclosure, in operation 1120, the memory system 200 (e.g., the host 210) may apply the transmission delay time to the transmission interval output from the memory 220. According to an embodiment of the disclosure, the memory system 200 (e.g., the host 210) may apply the transmission delay time (e.g., an offset) to the refresh interval tREFI corresponding to the refresh multiplier (or the refresh rate) stored in the register 225 (or the refresh multiplier output from the memory 220). In this case, the memory system 200 (e.g., the host 210) may postpone the transmission of the refresh command as much as the transmission delay time without transmitting the refresh command at the original transmission interval.

According to various embodiments of the disclosure, in operation 1130, the memory system 200 (e.g., the host 210) may transmit the refresh command to the memory 220 based on a second transmission interval to which the transmission time output from the memory 220 is applied.

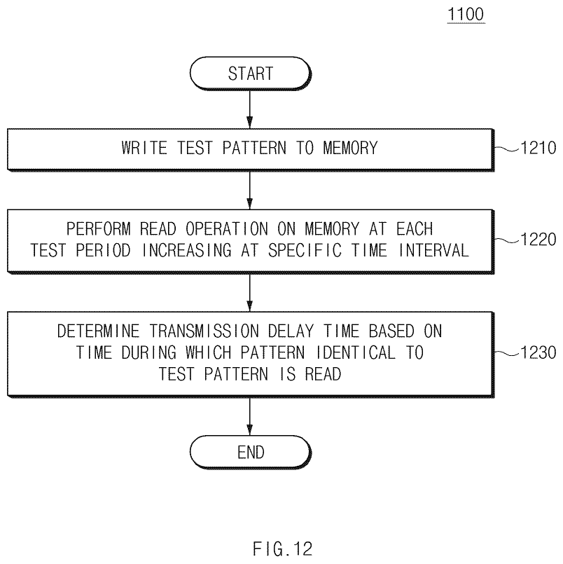

FIG. 12 is a flowchart illustrating an operation 1200 in which memory system determines a transmission delay time according to an embodiment of the disclosure.

Referring to FIG. 12, below, the description associated with FIG. 9 may be referenced in association with an operation to be described with reference to FIG. 12. Also, in the following embodiment of the disclosure, respective operations may be sequentially performed. However, the operations are not necessarily performed sequentially. For example, the order of the respective operations may be changed, and at least two of the operations may be performed in parallel. In addition, at least one of the operations described above may be omitted depending on an embodiment.

Referring to FIG. 12, in operation 1210, the memory system 200 (e.g., the host 210) according to various embodiments may write the test pattern to the memory 220. For example, the memory system 200 (e.g., the memory controller 221) may include an operation of writing data “1” (or “high data”) to the memory cell MC.

According to various embodiments of the disclosure, in operation 1220, the memory system 200 (e.g., the host 210) may perform an operation of reading the test pattern based on a test period which is increased at a given time interval.

According to various embodiments of the disclosure, in operation 1230, the memory system 200 (e.g., the host 210) may determine the transmission delay time based on a time when a pattern identical to the test pattern is read. For example, the memory system 200 (e.g., the host 210) may determine, as the transmission delay time, a time elapsed until just before a pattern different from the test pattern is read.

According to various embodiments of the disclosure, a method may include determining a first transmission delay time based on a first refresh period outputted from memory 130, applying the first transmission delay time to a refresh interval, transmitting a first refresh command to the memory 130 after a delay corresponding to an offset of the first transmission delay time based on a refresh interval (tREFI) corresponding to a second refresh period, when the second refresh period is outputted from the memory 130, and displaying a user interface that induces updating of the first transmission delay time to a second transmission delay time (or a user interface that induces updating of the first transmission delay time to a second transmission delay time), when a predetermined time expires after the first transmission delay time is determined.

According to various embodiments of the disclosure, the determining of the first transmission delay time may include writing a test pattern to the memory 130, performing a read operation on the memory 130 at each test period that increases by a specific time interval based on the refresh interval (tREFI) corresponding to the first refresh period, and determining the first transmission delay time based on a time during which a pattern identical to the test pattern is read.

According to various embodiments of the disclosure, the method may include determining the second transmission delay time based on a refresh interval (tREFI) corresponding to a third refresh period outputted from the memory 130, in response to receiving an input indicating the update to the second transmission delay time, applying the second transmission delay time to the refresh interval, and transmitting a second refresh command to the memory 130 after a delay corresponding to an offset of the second transmission delay time based on a refresh interval (tREFI) corresponding to a fourth refresh period, when the fourth refresh period is outputted from the memory.

According to various embodiments of the disclosure, the determining of the second transmission delay time may include writing a test pattern to the memory 130, performing a read operation on the memory 130 at each test period that increases by a specific time interval based on the refresh interval (tREFI) corresponding to the third refresh period, and determining the second transmission delay time based on a time during which a pattern identical to the test pattern is read.

According to various embodiments of the disclosure, a computer-readable recording medium may perform operations of writing a test pattern to the memory 220, performing, based on a refresh interval (tREFI) corresponding to a first refresh period outputted from the memory 220, a read operation on the memory 220 at each test period that increases by a specific time interval, determining a transmission delay time based on a time during which a pattern identical to the test pattern is read, applying the transmission delay time to a refresh interval (tREFI) corresponding to a refresh period outputted from the memory 220, applying the transmission delay time to the refresh interval, and transmitting a refresh command to the memory 220 after a delay corresponding to an offset of the transmission delay time based on a refresh interval (tREFI) corresponding to a second refresh period, when the second refresh period is outputted from the memory 220.

According to various embodiments of the disclosure, the at least one operation may include obtaining the first refresh period and the second refresh period from a register 225 in which a refresh period is updated based on a specific period.

According to various embodiments of the disclosure, the at least one operation may include obtaining a first refresh period and a second refresh period corresponding to an internal temperature of the memory 220.

According to various embodiments of the disclosure, the at least one operation may include obtaining a refresh period that is repeated at a certain level from among refresh periods outputted from the memory 220 for a specified time, as the first refresh period.

According to various embodiments of the disclosure, the at least one operation may include storing the transmission delay time to non-volatile memory 134, and obtaining the transmission delay time from the non-volatile memory 134 when the second refresh period is output from the memory.

It will be appreciated that various embodiments of the disclosure according to the claims and description in the specification can be realized in the form of hardware, software or a combination of hardware and software.

Any such software may be stored in non-transitory computer readable storage media. The non-transitory computer readable storage media store one or more computer programs (software modules), the one or more computer programs include computer-executable instructions that, when executed by one or more processors of an electronic device, cause the electronic device to perform a method of the disclosure.

Any such software may be stored in the form of volatile or non-volatile storage, such as, for example, a storage device like read only memory (ROM), whether erasable or rewritable or not, or in the form of memory, such as, for example, random access memory (RAM), memory chips, device or integrated circuits or on an optically or magnetically readable medium, such as, for example, a compact disk (CD), digital versatile disc (DVD), magnetic disk or magnetic tape or the like. It will be appreciated that the storage devices and storage media are various embodiments of non-transitory machine-readable storage that are suitable for storing a computer program or computer programs comprising instructions that, when executed, implement various embodiments of the disclosure. Accordingly, various embodiments provide a program comprising code for implementing apparatus or a method of any one of the claims of this specification and a non-transitory machine-readable storage storing such a program.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. An electronic device comprising:
a display;
memory, comprising one or more storage media, storing instructions including a refresh period; and
at least one processor communicatively coupled to the display and the memory,
wherein the instructions, when executed by the at least one processor individually or collectively, cause the electronic device to:
identify a first transmission delay time based on a refresh interval (tREFI) corresponding to a first refresh period identified based on the refresh period stored in the memory,
identify a second refresh period based on the refresh period stored in the memory after the first refresh period,
transmit a first refresh command to the memory after delaying the first transmission delay time based on a refresh interval corresponding to the second refresh period, and
display, via the display, a user interface that induces updating of the first transmission delay time to a second transmission delay time.

2. The electronic device of claim 1, wherein the instructions, when executed by the at least one processor individually or collectively, further cause the electronic device, in identifying the first transmission delay time, to:
write a test pattern to the memory,
perform a read operation on the memory at each test period that increases by specific time intervals based on the refresh interval corresponding to the first refresh period, and
identify the first transmission delay time based on a time at which a pattern identical to the test pattern is read.

3. The electronic device of claim 1, wherein the instructions, when executed by the at least one processor individually or collectively, further cause the electronic device to:
identify the second transmission delay time based on a refresh interval corresponding to a third refresh period identified based on the refresh period stored in the memory, in response to receiving an input to indicating update the first transmission delay time to the second transmission delay time,
identify a fourth refresh period based on the refresh period stored in the memory after the third refresh period, and
transmit a second refresh command to the memory after delaying by an offset of the second transmission delay time based on a refresh interval corresponding to the fourth refresh period.

4. The electronic device of claim 3, wherein the instructions, when executed by the at least one processor individually or collectively, further cause the electronic device, in identifying the second transmission delay time, to:
write a test pattern to the memory,
perform a read operation on the memory at each test period that increases by a specific time interval based on the refresh interval corresponding to the third refresh period, and
identify the second transmission delay time based on a time at which a pattern identical to the test pattern is read.

5. A memory system comprising:
volatile memory including a memory controller, comprising one or more storage media, storing instructions including a refresh period; and
at least one processor communicatively coupled to the volatile memory,
wherein the instructions, when executed by the at least one processor individually or collectively, cause the memory system to:
identify a transmission delay time (a) based on a refresh interval (tREFI) corresponding to a first refresh period outputted from the memory controller, and
identify a second refresh period outputted from the memory controller,
transmit a refresh command to the volatile memory after delaying the transmission delay time (a) based on a refresh interval (tREFI) corresponding to the second refresh period, and
wherein the instructions, when executed by the at least one processor individually or collectively, further cause the memory system, in identifying the transmission delay time, to:
write a test pattern to the volatile memory,
perform a read operation on the volatile memory at each test period that increases by specific time intervals based on the refresh interval corresponding to the first refresh period, and
identify the transmission delay time based on a time at which a pattern identical to the test pattern is read.

6. The memory system of claim 5, further comprising:
a register configured to update the refresh period based on a specific period,
wherein the instructions, when executed by the at least one processor individually or collectively, further cause the memory system to:
store the second refresh period to which the transmission delay time (a) is applied to the register.

7. The memory system of claim 6, wherein the register is configured to update the refresh period corresponding to an internal temperature of the volatile memory.

8. The memory system of claim 5, wherein the instructions, when executed by the at least one processor individually or collectively, further cause the memory system to:
obtain a refresh period that is repeated at a certain level among the refresh period outputted from the memory controller for a specified time, as the first refresh period.

9. The memory system of claim 5, further comprising:
non-volatile memory,
wherein the instructions, when executed by the at least one processor individually or collectively, further cause the memory system to:
store the transmission delay time to the non-volatile memory, and
apply the transmission delay time (a) to a refresh interval corresponding to the refresh period outputted from the memory controller.

10. One or more non-transitory computer-readable storage media storing one or more computer programs including computer-executable instructions that, when executed by one or more processors of an electronic device individually or collectively, cause the electronic device to perform operations, the operations comprising:
writing, by the electronic device, a test pattern to memory of the electronic device;
performing, by the electronic device, based on a refresh interval (tREFI) corresponding to a first refresh period identified based on a refresh period stored in the memory, a read operation on the memory at each test period that increases by a specific time interval;
identifying, by the electronic device, a transmission delay time based on a time at which a pattern identical to the test pattern is read;
identifying a second refresh period based on the refresh period stored in the memory after the first refresh period; and
transmitting, by the electronic device, a refresh command to the memory after delaying the transmission delay time based on a refresh interval corresponding to the second refresh period.

11. The one or more non-transitory computer-readable storage media of claim 10, the operations further comprising:
obtaining the first refresh period and the second refresh period from a register that is updated a refresh period based on a specific period.

12. The one or more non-transitory computer-readable storage media of claim 11, the operations further comprising:
obtaining the first refresh period and the second refresh period corresponding to an internal temperature of the memory.

13. The one or more non-transitory computer-readable storage media of claim 10, the operations further comprising:
obtaining a refresh period that is repeated at a certain level among the refresh period identified based on the refresh period stored in the memory for a specified time, as the first refresh period.

14. The one or more non-transitory computer-readable recording medium of claim 10, the operations further comprising:
storing the transmission delay time to non-volatile memory; and
transmitting the refresh command based on the transmission delay time stored in the non-volatile memory.

15. A method of operating an electronic device, the method comprising:
identifying, by the electronic device, a first transmission delay time based on a refresh interval (tREFI) corresponding to a first refresh period identified based on a refresh period stored in memory;
identifying a second refresh period based on the refresh period stored in the memory after the first refresh period;
transmitting, by the electronic device, a first refresh command to the memory after delaying the first transmission delay time based on a refresh interval corresponding to the second refresh period; and
displaying, by the electronic device, a user interface that induces updating of the first transmission delay time to a second transmission delay time.

16. The method of claim 15, further comprising:
writing, by the electronic device, a test pattern to the memory;
performing, by the electronic device, a read operation on the memory at each test period that increases by specific time intervals based on the refresh interval corresponding to the first refresh period; and
identifying, by the electronic device, the first transmission delay time based on a time at which a pattern identical to the test pattern is read.

17. The method of claim 15, further comprising:
identifying, by the electronic device, the second transmission delay time based on a refresh interval corresponding to a third refresh period identified based on the refresh period stored in the memory, in response to receiving an input to indicating update the first transmission delay time to the second transmission delay time;
identifying a fourth refresh period based on the refresh period stored in the memory after the third refresh period; and
transmitting, by the electronic device, a second refresh command to the memory after delaying by an offset of the second transmission delay time based on a refresh interval corresponding to the fourth refresh period.

18. The method of claim 17, further comprising:
writing, by the electronic device, a test pattern to the memory;
performing, by the electronic device, a read operation on the memory at each test period that increases by a specific time interval based on the refresh interval corresponding to the third refresh period; and
identifying, by the electronic device, the second transmission delay time based on a time at which a pattern identical to the test pattern is read.

19. The method of claim 15, further comprising:
when a predetermined time expires after the first transmission delay time is identified, displaying the user interface that induces updating of the first transmission delay time to the second transmission delay time.

20. The electronic device of claim 1, wherein the instructions, when executed by the at least one processor individually or collectively, further cause the electronic device to:
when a predetermined time expires after the first transmission delay time is identified, display the user interface that induces updating of the first transmission delay time to the second transmission delay time.
